(19) United States
(12) Patent Application Publication
(10) Pub. No.: US 2026/0011628 A1
(43) Pub. Date: Jan. 8, 2026

(54) Ideal Diode Chip

(71) Applicant: Wuxi Chipown Microelectronics Co., Ltd., Wuxi (CN)

(72) Inventors: Kun NIE, Wuxi (CN); Jian YIN, Wuxi (CN); Xiaowei LIN, Wuxi (CN); Yang LUO, Wuxi (CN); Sizhe HU, Wuxi (CN); Haisong LI, Wuxi (CN); Yangbo YI, Wuxi (CN)

(73) Assignee: Wuxi Chipown Microelectronics Co., Ltd., Wuxi (CN)

(21) Appl. No.: 19/023,228

(22) Filed: Jan. 15, 2025

(30) Foreign Application Priority Data
Jul. 4, 2024 (CN) 202410890306.2

(51) Int. Cl. H01L 23/495; H01L 23/00; H03K 17/687; H10D 84/80

(52) U.S. Cl. CPC H01L 23/49575; H01L 24/48; H03K 17/6871; H10D 84/813; H01L 2224/4813; H01L 2224/48245

(57) ABSTRACT

The present disclosure provides an ideal diode chip, including a first pin and a second pin arranged on a packaging frame. A power transistor and a first substrate are arranged on the first pin, and a switch transistor and a control module are arranged on the first substrate. The first pin serves as a cathode of the ideal diode chip, and the second pin serves as an anode of the ideal diode chip. The ideal diode chip according to the present disclosure can meet application requirements of different high voltage scenarios.

### CROSS-REFERENCE TO RELATED APPLICATION

This application claims the benefit of priority to Chinese patent application No. 202410890306.2, filed on Jul. 4, 2024, the entire disclosures of which is incorporated herein by reference.

### FIELD

The present disclosure relates to the technical field of ideal diodes, and more particularly to an ideal diode chip.

### BACKGROUND

Diodes generally operate in withstand voltage mode and conduction mode. Ordinary diodes have advantages of high current and high reverse withstand voltage, but also have a forward conduction voltage drop, thus Schottky diodes with a low forward conduction voltage are applied in some applications. However, in high current applications, Schottky diodes still generate heat, thus ideal diodes with a lower forward conduction voltage are applied in many applications.

As shown in FIG. 1, a circuit structure of an existing ideal diode typically includes a power transistor M1, a capacitor Cc and a control circuit A. The control circuit A includes a charge pump, a drive module and a switch transistor M2.

Referring to FIG. 1, when a channel of the power transistor M1 is turned off, current can flow through a body diode from a VIN end coupled with a source to a VOUT end coupled with a drain, and a voltage drop is formed cross the body diode. An anode of the body diode provides a positive voltage to the control circuit A. A source of the switch transistor M2 with a low threshold voltage in the control circuit A provides a chip ground potential for the drive module and the charge pump, which ensures that a supply voltage of the control circuit A is in a safe operating area. The charge pump pumps a voltage to a target value by obtaining the voltage drop of the body diode, and stores energy on the capacitor Cc. When the voltage of the capacitor Cc rises to the target value, the control circuit A causes the power transistor M1 to be conducted, and current flows through the channel from the VIN end to the VOUT end. Since on-resistance Rdson of the power transistor M1 is relatively small, the voltage drop from the VIN end to the VOUT end is very small. However, when the voltage at the VOUT end is much higher than the voltage at the VIN end, discrete power transistor M1 can withstand high voltage, while the source and drain of the switch transistor M2 will experience a large voltage drop, thus the switch transistor M2 needs to have high voltage withstand capability. In conventional BCD (a technology that integrates Bipolar (Bipolar Transistor), CMOS (Complementary Metal Oxide Semiconductor) and DMOS (Double Diffusion Metal Oxide Semiconductor) on a same chip) process, the switch transistor in the ideal diode shown in FIG. 1 cannot meet requirements of low threshold and high withstand voltage, thus a reverse withstand voltage and application scenarios of the ideal diodes are limited, and thus the ideal diodes cannot meet application requirements of some high voltage scenarios. Moreover, even if the switch transistor can meet high voltage requirements, control circuit may still need to be changed due to different withstand voltage requirements.

### SUMMARY

An embodiment of the present disclosure provides an ideal diode chip to solve a problem that existing ideal diodes have limited voltage withstand capability and cannot meet application requirements of high voltage scenarios.

According to an embodiment of the present disclosure, an ideal diode chip is provided. The ideal diode chip includes a first pin and a second pin arranged on a packaging frame. A power transistor and a first substrate are arranged on the first pin, and a switch transistor and a control module are arranged on the first substrate. The first pin serves as a cathode of the ideal diode chip, and the second pin serves as an anode of the ideal diode chip.

According to some embodiments, a first contact point, a second contact point, a third contact point and a fourth contact point are provided on one side of the power transistor. The first contact point is coupled with a source of the power transistor, and the second contact point is coupled with a gate of the power transistor. The third contact point is coupled with a drain of the power transistor, and the fourth contact point is coupled with the first contact point.

According to some embodiments, the other side of the power transistor is coupled with the first pin as one port of the source of the power transistor.

According to some embodiments, the fourth contact point on the power transistor is simultaneously coupled with the second pin.

According to some embodiments, an area of the fourth contact point on the power transistor is greater than an area of other contact points on the power transistor.

According to some embodiments, the switch transistor is provided with a fifth contact point, a sixth contact point and a seventh contact point. The fifth contact point is coupled with a drain of the switch transistor, the sixth contact point is coupled with a gate of the switch transistor, and the seventh contact point is coupled with a source of the switch transistor.

According to some embodiments, the control module is provided with a first control point, a second control point, a third control point, a fourth control point, a fifth control point and a sixth control point. The first control point is coupled with the anode of the ideal diode chip to provide an energy source for a control circuit, and the second control point is coupled with the gate of the power transistor. The fourth control point provides a reference ground for the control module, the first control point is also coupled with the third control point, and the fifth control point and the sixth control point are coupled with a capacitor. The first control point on the control module is coupled with the first contact point on the power transistor, and the second control point on the control module is coupled with the second contact point on the power transistor. The third control point on the control module is coupled with the sixth contact point on the switch transistor, and the fourth control point on the control module is coupled with the fifth contact point on the switch transistor.

According to some embodiments, the third contact point on the power transistor is coupled with the seventh contact point on the switch transistor.

According to some embodiments, the first substrate is further provided with a capacitor, a first connection point and a second connection point. One end of the capacitor is coupled with the first connection point through a metal trace, and the other end is coupled with the second connection point through a metal trace. The fifth control point on the control module is coupled with the second connection point on the first substrate, and the sixth control point on the control module is coupled with the first connection point on the first substrate.

According to some embodiments, the ideal diode chip further includes a third pin arranged on the packaging frame. The fourth contact point on the power transistor is coupled with the third pin and the second pin.

According to some embodiments, the ideal diode chip further includes a third pin and a fourth pin arranged on the packaging frame. The fifth control point on the control module is coupled with the third pin, and the sixth control point on the control module is coupled with the fourth pin.

According to some embodiments, the first pin simultaneously serves as a heat dissipation pad.

According to the embodiments of the present disclosure, the ideal diode chip separates the switch transistor from a control circuit of an ideal diode, that is, using a separate switch transistor and sealing the switch transistor with the control module, which not only solves the problem of limited withstand voltage of the ideal diode, but also allows for different configurations of high voltage switch transistor according to different requirements. By adopting this packaging structure, the control circuit can be made using a low voltage technology, which can greatly save process costs, facilitate selecting of suitable switch transistors according to different withstand voltage requirements, increase product flexibility and can better meet application requirements of different scenarios.

### BRIEF DESCRIPTION OF THE DRAWINGS

FIG. 1 illustrates a schematic structural view of a circuit structure of an existing ideal diode;

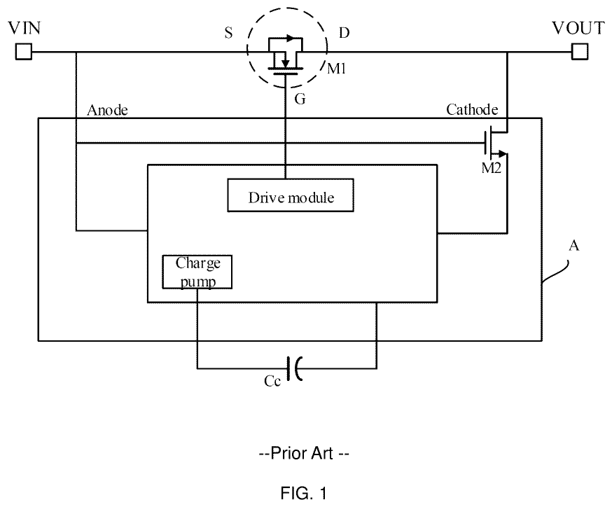

FIG. 2 illustrates a schematic structural view of an ideal diode chip according to an embodiment of the present disclosure;

FIG. 3 illustrates a schematic structural view of a package wire bonding configuration of the ideal diode chip in FIG. 2;

FIG. 4 illustrates a specific schematic structural view of an ideal diode chip according to an embodiment of the present disclosure;

FIG. 5 illustrates a schematic structural view of a package wire bonding configuration of the ideal diode chip in FIG. 4;

FIG. 6 illustrates a back structural view of the ideal diode chip in FIG. 5;

FIG. 7 illustrates a schematic structural view of an ideal diode chip according to still another embodiment of the present disclosure;

FIG. 8 illustrates a schematic structural view of a package wire bonding configuration of the ideal diode chip in FIG. 7; and

FIG. 9 illustrates a back structural view of the ideal diode chip in FIG. 8.

### DETAILED DESCRIPTION

In order to make above purposes, features and effects of the present disclosure more obvious and understandable, specific embodiments of the present disclosure will be described in detail below in combination with the attached drawings.

In conventional BCD process, due to limitations of high voltage process conditions, a voltage withstand capability of a switch transistor integrated in a control circuit is limited, which cannot meet application requirements of some high voltage scenarios. If a low voltage switch transistor is replaced with a high voltage switch transistor, the control circuit will need to be manufactured under high voltage technology, which will not only greatly increase production costs, but also make it difficult for manufacturers to provide corresponding process technology at present.

Therefore, an embodiment of the present disclosure provides an ideal diode chip, which separates the switch transistor from the control circuit of the ideal diode and seals the switch transistor with the control circuit, which not only solves the problem of limited voltage withstand capability of the ideal diode, but also allows for different configurations of high voltage switch transistor according to different requirements.

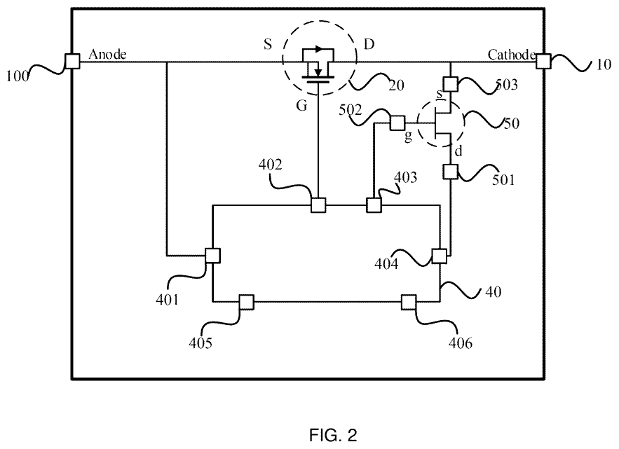

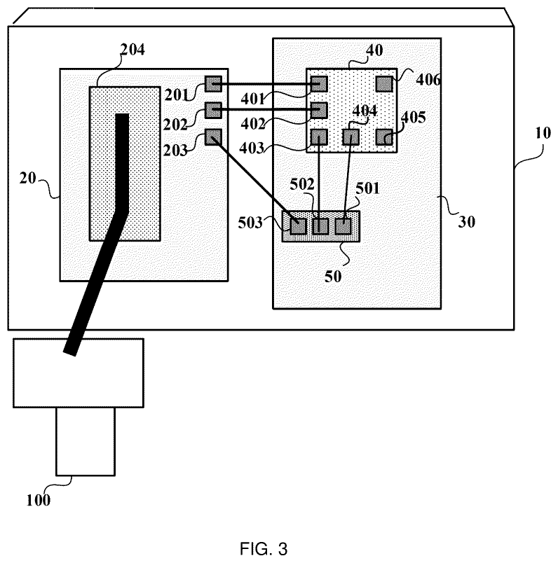

FIG. 2 illustrates a schematic structural view of an ideal diode chip according to an embodiment of the present disclosure, and FIG. 3 illustrates a schematic structural view of a package wire bonding configuration of the ideal diode chip in FIG. 2.

Referring to FIGS. 2 and 3, the ideal diode chip includes a first pin 10 and a second pin 100 arranged on a packaging frame. A power transistor 20 and a first substrate 30 are arranged on the first pin 10, and a switch transistor 50 and a control module 40 are arranged on the first substrate 30.

The power transistor 20 is configured to provide a starting voltage for the control module 40 when a channel is turned off.

The control module 40 is configured to output a power supply voltage according to the starting voltage.

The switch transistor 50 is configured to ensure a power supply voltage input by the control module 40 in a safe operating area.

In some embodiments, the first pin 10 serves as a cathode of the ideal diode chip, and the second pin 100 serves as an anode of the ideal diode chip. The first pin 10 and the second pin 100 are made of a conductive material, such as copper or metal alloy. An area of the first pin 10 is greater than an area of the second pin 100, and the first pin 10 can also serve as a heat dissipation pad.

It should be noted that in some embodiments of the present disclosure, the power transistor 20 may be a MOS transistor, an IGBT (Insulated Gate Bipolar Transistor) or a BJT (Bipolar Junction Transistor). For example, the power transistor 20 is a MOS transistor. The switch transistor 50 may be selected from one of the following: a MOS transistor, a JFET (Junction Field-effect Transistor) or an SCR (Thyristor). For example, the switch transistor 50 is a MOS transistor.

The power transistor 20 and the switch transistor 50 in the embodiments shown in FIGS. 2 and 3 are illustrated using NMOS transistors as an example. The use of other types of power transistors and switch transistors can be adaptively adjusted based on the same principle for the connection between pins, and the present disclosure is not limited to this. The structure of the switch transistor 50 independent from the control module 40 falls within the scope of the embodiments of the present disclosure.

Still referring to FIGS. 2 and 3, the power transistor 20 includes a source S, a gate G, and a drain D. Correspondingly, as shown in FIG. 3, a first contact point 201, a second contact point 202, a third contact point 203 and a fourth contact point 204 are provided on one side of the power transistor 20. The first contact point 201 is coupled with the source S of the power transistor 20, the second contact point 202 is coupled with the gate G of the power transistor 20, and the third contact point 203 is coupled with the drain D of the power transistor 20.

The fourth contact point 204 is coupled with the second pin 100 as a power input end. Correspondingly, the first contact point 201 is coupled with the fourth contact point 204. To ensure a reliability of the connection, an area of the fourth contact point 204 may be greater than an area of other contact points on the power transistor 20.

The other side of the power transistor 20 is coupled with the first pin 10 as one port of the source S of the power transistor 20.

The switch transistor 50 is provided with a fifth contact point 501, a sixth contact point 502 and a seventh contact point 503. The fifth contact point 501 is coupled with a drain d of the switch transistor 50, the sixth contact point 502 is coupled with a gate g of the switch transistor 50, and the seventh contact point 503 is coupled with a source s of the switch transistor 50.

The control module 40 is provided with a first control point 401, a second control point 402, a third control point 403, a fourth control point 404, a fifth control point 405 and a sixth control point 406.

The first control point 401 is coupled with the anode of the ideal diode chip to provide an energy source for the control circuit. The second control point 402 is coupled with the gate G of the power transistor 20. The fourth control point 404 provides a reference ground for the control module 40. The first control point 401 is also coupled with the third control point 403.

The first control point 401 on the control module 40 is coupled with the first contact point 201 on the power transistor 20. The second control point 402 on the control module 40 is coupled with the second contact point 202 on the power transistor 20. The third control point 403 on the control module 40 is coupled with the sixth contact point 502 on the switch transistor 50. The fourth control point 404 on the control module 40 is coupled with the fifth contact point 501 on the switch transistor 50.

Further, the third contact point 203 on the power transistor 20 is coupled with the seventh contact point 503 on the switch transistor 50.

It should be noted that the fifth control point 405 and the sixth control point 406 on the control module 40 are configured to connect a capacitor. In specific embodiments, the capacitor may be provided on the first substrate 30 or an external capacitor may be provided, and the present disclosure is not limited to this. The following description will further explain these two different connection methods.

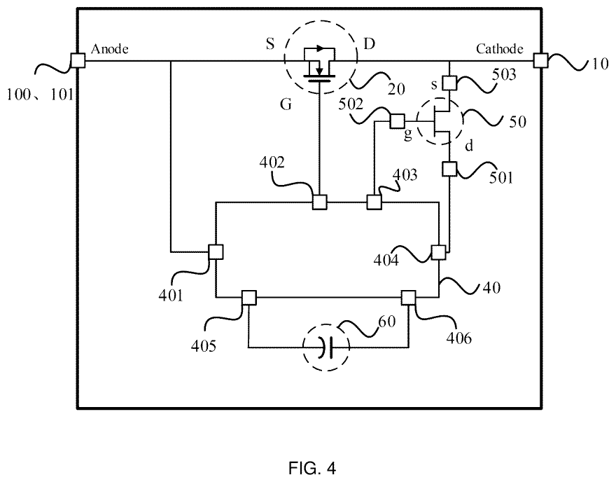

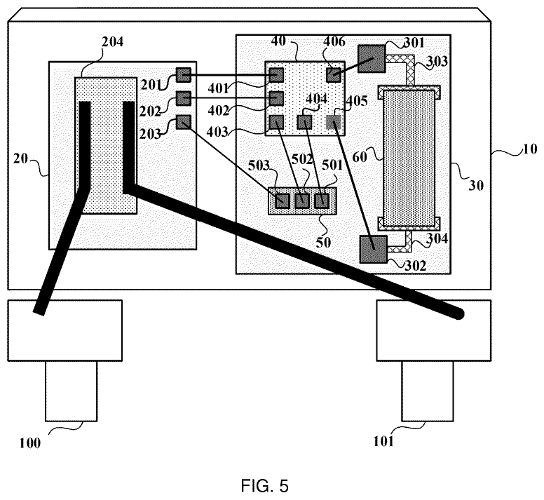

FIG. 4 illustrates a specific schematic structural view of an ideal diode chip according to an embodiment of the present disclosure, and FIG. 5 illustrates a schematic structural view of a package wire bonding configuration of the ideal diode chip in FIG. 4.

Referring to FIGS. 4, 5 and 6, the ideal diode chip also includes a capacitor 60. The capacitor 60 is provided on the first substrate 30 for storing energy under a power supply voltage output by the control module 40.

Correspondingly, the first substrate 30 is also provided with a first connection point 301 and a second connection point 302. One end of the capacitor 60 is coupled with the first connection point 301 through a metal trace 303, and the other end is coupled with the second connection point 302 through a metal trace 304. In addition, the fifth control point 405 on the control module 40 is coupled with the second connection point 302 on the first substrate 30, and the sixth control point 406 on control module 40 is coupled with the first connection point 301 on the first substrate 30.

Further, in order to meet different packaging pin requirements, as shown in FIG. 5, in a non-limiting embodiment, the ideal diode chip may further include a third pin 101 provided on the packaging frame. The third pin 101 is also made of a conductive material, such as copper or metal alloy. Correspondingly, the second pin 100 and the third pin 101 are coupled with the fourth contact point 204 as a power input end.

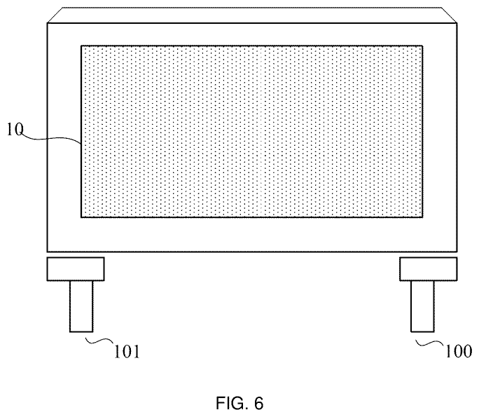

FIG. 6 illustrates a back structural of the ideal diode chip in FIG. 5.

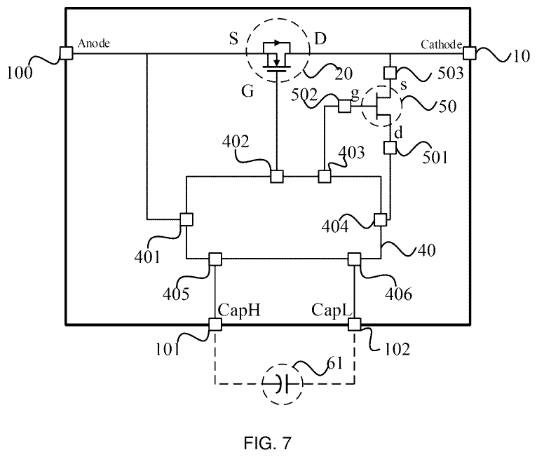

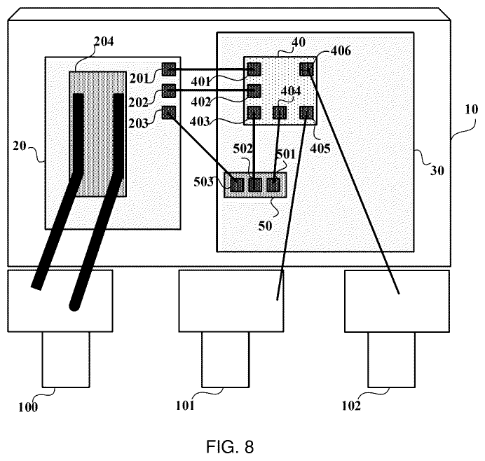

FIG. 7 illustrates a schematic structural view of an ideal diode chip according to still another embodiment of the present disclosure, and FIG. 8 illustrates a schematic structural view of a package wire bonding configuration of the ideal diode chip in FIG. 7.

Unlike the embodiment shown in FIG. 4, the ideal diode chip of this embodiment does not include the capacitor 60 in FIG. 5, and an external capacitor 61 is provided for use with the ideal diode chip.

Referring to FIGS. 7 and 8, due to the need for an external capacitor, in this embodiment, the ideal diode chip includes four pins arranged on the packaging frame, namely a first pin 10, a second pin 100, a third pin 101 and a fourth pin 102. Similarly, these four pins are also made of a conductive material, such as copper or metal alloy.

The connection relationship between the first pin 10 and the second pin 100 is the same as the embodiment shown in FIG. 3. The first pin 10 serves as the cathode of the ideal diode chip, and the second pin 100 serves as the anode of the ideal diode chip.

The fifth control point 405 on the control module 40 is coupled with the third pin 101, and the sixth control point 406 on the control module 40 is coupled with the fourth pin 102. The connection method of other control points on the control module 40 is the same as the embodiment shown in FIG. 3, which will not be repeated herein.

In addition, the structure and connection method of the power transistor 20 on the first pin and the switch transistor 50 on the first substrate 30 are the same as the embodiment shown in FIG. 3, which will not be repeated herein.

As shown in FIGS. 7 and 8, when coupled with the external capacitor 61, one end of capacitor 61 is coupled with the third pin 101, and the other end is coupled with the fourth pin 102.

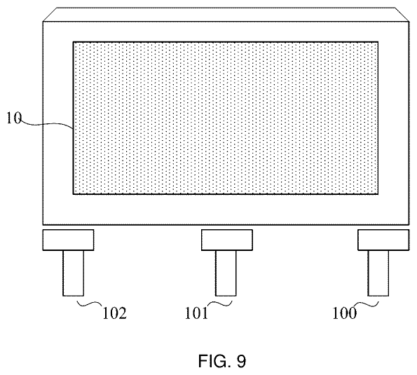

FIG. 9 illustrates a back structure of the ideal diode chip in FIG. 8.

It should be noted that in the embodiments of the present disclosure, “coupled” refers to “electrically coupled”, and the specific connection method can be metal trace connection, bonding, or conductive adhesive connection. For example, in the embodiment shown in FIG. 5, the first control point 401 on the control module 40 is coupled with the first contact point 201 of the power transistor 20 by bonding, and the fourth contact point 204 on the power transistor 20 is coupled with the second pin 100 and the third pin 101 by bonding. The other side of the power transistor 20 serves as one port of the source of the power transistor 20 and is coupled with the first pin through a conductive adhesive. One end of the capacitor 60 is coupled with the first connection point 301 on the first substrate 30 through a metal trace, and the other end is coupled with the second connection point 302 through a metal trace.

In addition, the terms “contact point”, “connection point” and “control point” in the embodiments of the present disclosure are electrical connection points of the same nature, and distinguished corresponding to different components only for ease of description and without essential differences. In actual products, they can specifically be soldering points, connection points, or connection points between metal lines and solder pads, or connection points between traces and solder pads in PCB boards, etc., and the embodiments of the present disclosure are not limited to this.

The ideal diode chip according to the present disclosure utilizes discrete switch transistors, allowing high voltage field-effect transistors (including junction field-effect transistors and high voltage MOSFETs) to replace conventional switch transistors, enabling the switch transistors to withstand most of the voltage during operation and reducing the voltage applied to the control module. By combining the switch transistor with the control module, the pressure of process matching is greatly reduced, while the reverse withstand voltage of the ideal diode is improved, which can expand the application scenarios of the ideal diode.

By utilizing discrete switch transistor and sealing the switch transistor with the control module, the control circuit can be made using a low voltage technology, which can greatly save process costs, facilitate selecting of suitable switch transistors according to different withstand voltage requirements, increase product flexibility and can better meet application requirements of different scenarios.

Furthermore, the capacitor is integrated into the packaging structure, which can simplify peripheral components of the ideal diode chip, make peripheral circuits simpler, facilitate miniaturization design of products and effectively save costs.

It should be understood that the term “and/or” in the present disclosure is merely an association relationship describing associated objects, indicating that there can be three types of relationships, for example, A and/or B can represent “A exists only, both A and B exist, and B exists only. In addition, the character “/” in the present disclosure represents that the former and latter associated objects have an “or” relationship.

The “plurality” in the embodiments of the present disclosure refers to two or more.

The “first”, “second” in the embodiments of the present disclosure are only used for illustrating and distinguishing description objects, and have no sequence limitation, nor do they represent a special limitation on the number of devices in the embodiments of the present disclosure, and do not constitute any limitation to the embodiments of the present disclosure.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

What is claimed is:

1. An ideal diode chip, comprising a first pin and a second pin arranged on a packaging frame, wherein a power transistor and a first substrate are arranged on the first pin, and a switch transistor and a control module are arranged on the first substrate, wherein the first pin serves as a cathode of the ideal diode chip, and the second pin serves as an anode of the ideal diode chip.

2. The ideal diode chip according to claim 1, wherein a first contact point, a second contact point, a third contact point and a fourth contact point are provided on one side of the power transistor, wherein the first contact point is coupled with a source of the power transistor, the second contact point is coupled with a gate of the power transistor, the third contact point is coupled with a drain of the power transistor, and the fourth contact point is coupled with the first contact point.

3. The ideal diode chip according to claim 2, wherein the other side of the power transistor is coupled with the first pin as one port of the source of the power transistor.

4. The ideal diode chip according to claim 2, wherein the fourth contact point on the power transistor is simultaneously coupled with the second pin.

5. The ideal diode chip according to claim 4, wherein an area of the fourth contact point on the power transistor is greater than an area of other contact points on the power transistor.

6. The ideal diode chip according to claim 2, wherein the switch transistor is provided with a fifth contact point, a sixth contact point and a seventh contact point, wherein the fifth contact point is coupled with a drain of the switch transistor, the sixth contact point is coupled with a gate of the switch transistor, and the seventh contact point is coupled with a source of the switch transistor.

7. The ideal diode chip according to claim 6, wherein the control module is provided with a first control point, a second control point, a third control point, a fourth control point, a fifth control point and a sixth control point, wherein the first control point is coupled with the anode of the ideal diode chip to provide an energy source for a control circuit, the second control point is coupled with the gate of the power transistor, the fourth control point provides a reference ground for the control module, the first control point is also coupled with the third control point, and the fifth control point and the sixth control point are coupled with a capacitor; and
wherein the first control point on the control module is coupled with the first contact point on the power transistor, the second control point on the control module is coupled with the second contact point on the power transistor, the third control point on the control module is coupled with the sixth contact point on the switch transistor, and the fourth control point on the control module is coupled with the fifth contact point on the switch transistor.

8. The ideal diode chip according to claim 7, wherein the third contact point on the power transistor is coupled with the seventh contact point on the switch transistor.

9. The ideal diode chip according to claim 7, wherein the first substrate is further provided with a capacitor, a first connection point and a second connection point; and one end of the capacitor is coupled with the first connection point through a metal trace, and the other end is coupled with the second connection point through a metal trace; and
wherein the fifth control point on the control module is coupled with the second connection point on the first substrate, and the sixth control point on the control module is coupled with the first connection point on the first substrate.

10. The ideal diode chip according to claim 9, further comprising a third pin arranged on the packaging frame, wherein the fourth contact point on the power transistor is coupled with the third pin and the second pin.

11. The ideal diode chip according to claim 7, further comprising a third pin and a fourth pin arranged on the packaging frame, wherein the fifth control point on the control module is coupled with the third pin, and the sixth control point on the control module is coupled with the fourth pin.

12. The ideal diode chip according to claim 1, wherein the first pin simultaneously serves as a heat dissipation pad.
